(19) United States
(12) Patent Application Publication
(10) Pub. No.: US 2015/0279880 A1
(43) Pub. Date: Oct. 1, 2015

(54) BACKSIDE ILLUMINATED IMAGE SENSOR AND METHOD OF MANUFACTURING THE SAME

(71) Applicant: TAIWAN SEMICONDUCTOR MANUFACTURING COMPANY LTD., HSINCHU (TW)

(72) Inventors: SHIU-KO JANGJIAN, TAINAN CITY (TW); CHUN CHE LIN, TAINAN CITY (TW); YU-KU LIN, TAINAN CITY (TW); YING-LANG WANG, TAI-CHUNG COUNTY (TW); CHUAN-PU LIU, TAINAN CITY (TW)

(73) Assignee: TAIWAN SEMICONDUCTOR MANUFACTURING COMPANY LTD., Hsinchu (TW)

(21) Appl. No.: 14/230,060

(22) Filed: Mar. 31, 2014

(51) Int. Cl. H01L 27/146

(52) U.S. Cl. CPC H01L 27/1464; H01L 27/14636; H01L 27/14643; H01L 27/14689; H01L 27/14687

(57) ABSTRACT

A backside illuminated (BSI) image sensor device includes: a substrate including a front side and a back side; a multilayer structure over the back side; and a radiation-sensing region in the substrate. The radiation-sensing region is configured to receive a radiation wave entering from the back side and transmitting through the multilayer structure. The multilayer structure includes a first high-k dielectric layer, a metal silicide layer and a second high-k dielectric layer. The first high-k dielectric layer is located over the back side. The metal silicide layer is sandwiched between the first high-k dielectric layer and the second high-k dielectric layer.

### FIELD

The present disclosure relates to a semiconductor image sensor.

### BACKGROUND

Semiconductor image sensors are used for sensing light. Complementary metal-oxide-semiconductor (CMOS) image sensors (CIS) and charge-coupled device (CCD) sensors are widely used in various applications such as digital still camera or mobile phone camera applications.

A backside illuminated (BSI) image sensor device is one type of image sensor device. Image pixels in the BSI image sensor device generate electrical signals in response to incident light. Magnitudes of the electrical signals depend on the intensity of the incident light received by the respective image pixels. However, as the size of transistor devices shrinks with each technological generation, existing BSI image sensor devices may begin to suffer from issues related to electrical or optical crosstalk. For example, unwanted current may be generated in the absence of illumination. This unwanted current is known as the dark current. Excessive dark current may cause image degradation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are cross-sectional views illustrating a backside illuminated (BSI) image sensor device in accordance with some embodiments of the present disclosure.

FIGS. 2A-2C are three-dimensional views illustrating multilayer structures in accordance with some embodiments of the present disclosure.

FIGS. 3A-3E represent a method of manufacturing a backside illuminated (BSI) image sensor device as in FIG. 1 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An “image pixel”, as used herein, refers to a device used to capture photons, and generate electrical signals from the received photons. In some embodiments, the image pixel includes a photodiode, a transfer transistor, a floating diffusion region, a reset transistor, a source follower (common drain amplifier), and a select transistor, which is typically called a 4-T image sensor. It should be appreciated that embodiments of the present disclosure are not limited to 4-T image pixel architectures; rather, one of ordinary skill in the art having the benefit of the instant disclosure will understand that the present disclosure is also applicable to 3-T designs, 5-T designs, and various other image pixel architectures. During operation, incident light is received by the photodiode. Electron-hole pairs are generated in response to the received light. The electrons are then collected in the photodiode and transferred to the floating diffusion region via the transfer transistor. Later, the electrons are converted into electrical signals to be received. The reset transistor is coupled between a power V_{DD} and the floating diffusion region so as to reset the floating diffusion region to a preset voltage. The floating diffusion region is coupled to control the gate of the source follower. The source follower is coupled between the power V_{DD} and the select transistor. The source follower is configured to provide an infinite input resistance reduced to a small output resistance. The source follower is typically used as a voltage buffer. Such resistance reduction provides the combination for a more ideal voltage source. Finally, the select transistor selectively couples the output of the image pixel to a readout column line or a readout row line.

The terms “wafer” and “substrate,” as used herein, are to be understood as including silicon, silicon-on-insulator (SOI) technology, silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor does not need to be silicon-based, but could be based on silicon-germanium, germanium, gallium arsenide or other semiconductor structures.

The term “isolation,” as used herein, refers to an oxide structure or a dielectric structure for isolating devices. There are two typical formation processes, one is Local Oxidation of Silicon (LOCOS) and the other is Shallow Trench Isolation (STI). In an image sensor, the isolation is disposed between image pixels and adjacent image pixels so as to isolate the adjacent image pixels. In addition, the isolation is configured to act as a barrier to keep charge carriers (holes or electrons) from penetrating into an adjacent image pixel.

The terms “deposition” and “deposit,” as used herein, refer to operations of depositing materials on a substrate using a vapor phase of a material to be deposited, a precursor of the material, and an electrochemical reaction or sputtering/reactive sputtering. Depositions using a vapor phase of a material include any operations such as, but not limited to, chemical vapor deposition (CVD) and physical vapor deposition (PVD). Examples of vapor deposition methods include hot filament CVD, rf-CVD, laser CVD (LCVD), conformal diamond coating operations, metal-organic CVD (MOCVD), thermal evaporation PVD, ionized metal PVD (IMPVD), electron beam PVD (EBPVD), reactive PVD, atomic layer deposition (ALD), plasma enhanced CVD (PECVD), high density plasma CVD (HDPCVD), low pressure CVD (LPCVD), and the like. Examples of deposition using an electrochemical reaction include electroplating, electro-less plating, and the like. Other examples of deposition include pulse laser deposition (PLD) and atomic layer deposition (ALD).

In a backside illuminated (BSI) image sensor device, transistors are formed on a front side of the substrate. Further, photodiodes are formed in the substrate. A back side of the substrate is thinned to reduce absorption of incident light by substrate material. Thus, the incident light is allowed to pass to the photodiodes from the back side of the substrate. Unfortunately, the back side is subject to an undesirable amount of bubble defects and/or dark currents (DC) after a thinning process or a deposition. The thinning processes are used to scrub or polish the back side resulting in defects (such as dangling bonds or interface charges). These defects are physical defects or electrical defects and could trap carriers, such as electrons or holes. The trapped carriers produce leakage current, which is a serious problem for image sensors. For example, with a sufficient amount of leakage current, the radiation-sensing regions falsely detect radiation waves even when the image pixels are placed in an optically dark environment. In this situation, the leakage current refers to dark current. The dark current forms electrical crosstalk and degrades the performance of the image pixels. The dark current also causes a white pixilation where an excessive amount of current leakage causes an abnormally high signal for the BSI image sensor device.

In order to solve the problem of dark currents, a first high-k dielectric layer is deposited on a back side of the substrate. The first high-k dielectric layer has negative charges at an interface with the substrate and in itself overall. The negative charges create a depletion layer close to the interface and in the substrate that reduces dark current. Sometimes, a single high-k dielectric layer is unstable and vulnerable to oxidation. The negative charges in the first high-k dielectric layer can disappear or be neutralized, thereby causing the negative charges to no longer provide any advantages. A second high-k dielectric layer with a higher chemical stability is used to cap the first high-k dielectric layer. The second high-k dielectric layer provides chemical stability for the first high-k dielectric layer. However, the second high-k atoms have a tendency to diffuse into the first high-k dielectric layer during a sequential thermal process, thus causing the negative charge property to disappear or become neutralized. This results in poor electrical performance; for example, dark current (DC) and white pixel (WP) degradation.

The present disclosure provides a barrier between the first and second high-k dielectric layers. The barrier is made of a high-k silicide layer that provides a diffusion block layer and a better adhesion between the first and second high-k dielectric layers. Due to the high-k silicide layer, high-k atoms of the second high-k dielectric layer are blocked in a sequential thermal process. The negative charge property remains on the back side of the substrate. Thus, the dark current and white pixel degradation are reduced.

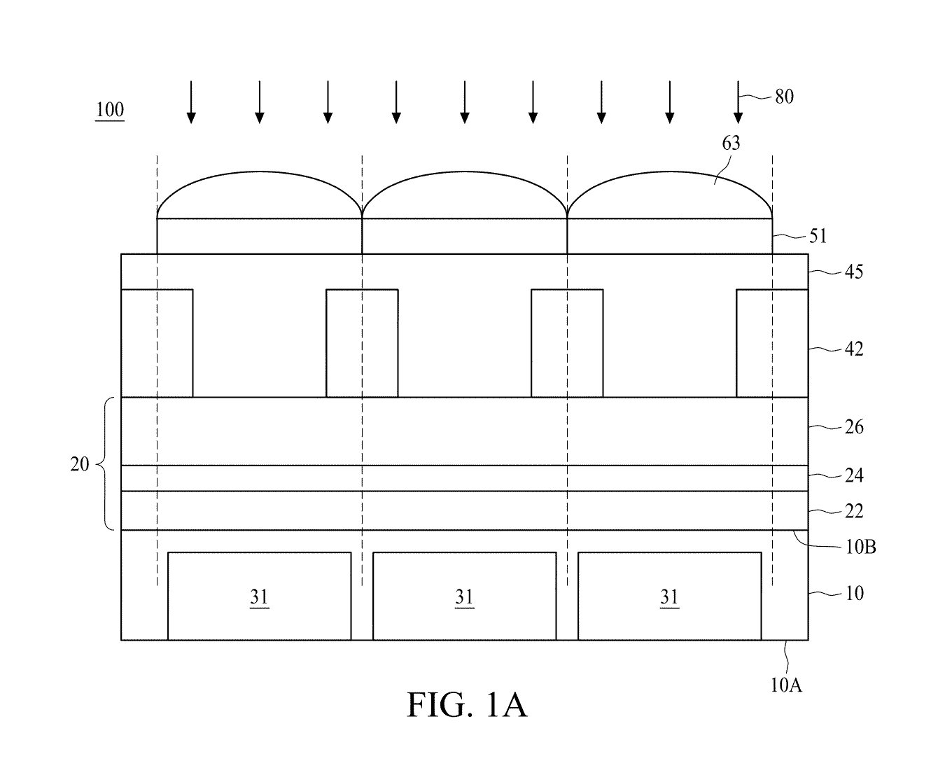

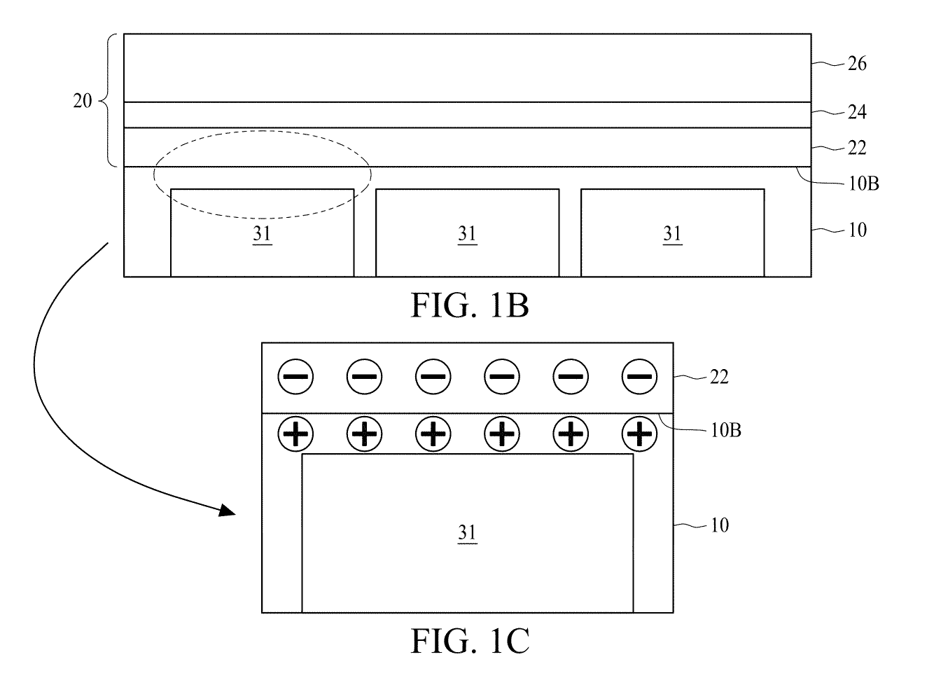

In reference to the Figures, FIGS. 1A-1C are cross-sectional views illustrating a backside illuminated (BSI) image sensor device 100 in accordance with some embodiments of the present disclosure. The BSI image sensor device 100 includes a substrate 10, radiation-sensing regions 31, a multilayer structure 20, a metal grid 42, color filters 51, and micro lenses 63. The multilayer structure 20 further includes a first high-k dielectric layer 22, a metal silicide layer 24 and a second high-k dielectric layer 26.

The substrate 10 further includes a front side 10A and a back side 10B. The radiation-sensing regions 31 are disposed in the substrate 10. Shallow trench isolations (not shown) are located on the front side 10A. Each shallow trench isolation separates adjacent radiation-sensing regions 31. The multilayer structure 20 is disposed on the back side 10B. The metal grid 42 is disposed on the multilayer structure 20. A dielectric layer 45 is filled in the metal grid 42. The color filters 51 are disposed over the metal grid 42. The micro lenses 63 are disposed on the color filters 51.

At least one image pixel (not shown) is disposed on the front side 10A. The image pixel further includes a radiation-sensing region 31. The radiation-sensing region 31 is formed in the substrate 10. In addition, the radiation-sensing region 31 is configured to receive a radiation wave 80 entering from the back side 10B and transmitting through the multilayer structure 20. The radiation-sensing region 31 is implemented as a photodiode, a pinned photodiode, or a p-n junction disposed in the substrate 10. The radiation-sensing region 31 receives the radiation wave 80 from an image so as to sense or detect radiation waves at specific wavelengths, which may correspond to lights of different colors. Further, the radiation-sensing region 31 receives photons from the radiation wave 80 and converts the radiation wave 80 into an electrical signal. The radiation wave 80 induces the radiation-sensing region 31 in order to generate electron-hole pairs in a depletion region of the radiation-sensing region 31.

The multilayer structure 20 is disposed over the back side 10B. The multilayer structure 20 includes a thickness from about 100 angstroms to 1000 angstroms. The multilayer structure 20 includes a first high-k dielectric layer 22, a metal silicide layer 24 and a second high-k dielectric layer 26. The first high-k dielectric layer 22 is located over the back side 10B. The metal silicide layer 24 is sandwiched between the first high-k dielectric layer 22 and the second high-k dielectric layer 26. The first and second high-k dielectric layers (22, 26) are made of high-k dielectric materials having a k value higher than 3.9 or higher than 8.0. Exemplary high-k dielectric materials include HfO₂, ZrO₂, La₂O₃, Al₂O₃, TiO₂, SrTiO₃, LaAlO₃, Al₂OₓN_{y}, Y₂O₃, LaAlOₓN_{y}, HfOₓN_{y}, ZrOₓN_{y}, La₂OₓN_{y}, TiOₓN_{y}, SrTiOₓN_{y}, Y2OₓN_{y}, and an alloy thereof. Each value of x is independently distributed from 0.1 to 3.

In some embodiments, the first high-k dielectric layer 22 includes a high-k metal that is different from that of the second high-k dielectric layer 26. The first high-k dielectric layer 22 is selected from a group consisting of HfO₂ and La₂O₃. The hafnium oxide or lanthanum oxide includes a high concentration of negative charges. As such, the first high-k dielectric layer 22 includes negative charges at an interface with the substrate 10 and in itself overall. The first high-k dielectric layer 22 includes a thickness from about 10 angstroms to 100 angstroms. The first high-k dielectric layer 22 is able to repair damage and defects on the back side 10B that are induced by process, for example, a thinning process applied on substrate 10. The defects on the back side 10B trap electrons and induce negative charges that cause dark currents. By means of the first high-k dielectric layer 22, the defects on the back side 10B are repaired and depleted so that the dark current can be reduced.

The second high-k dielectric layer 26 is selected from a group consisting of ZrO₂, Ta₂O₅, Al₂O₃, and TiO₂. As such, the second high-k dielectric layer 26 has a lower standard electrode potential than the first high-k dielectric layer 22. That is, the second high-k dielectric layer 26 with a higher chemical stability is used to cap over the first high-k dielectric layer 22. The second high-k dielectric layer 26 provides chemical stability and prevents the first high-k dielectric layer 22 from being exposed to oxidation. The second high-k dielectric layer 26 includes a thickness from about 80 angstroms to 900 angstroms.

The metal silicide layer 24 is sandwiched between the first high-k dielectric layer 22 and the second high-k dielectric layer 26. The metal silicide layer 24 includes a high-k metal that is the same as that of the first high-k dielectric layer 22 or the second high-k dielectric layer 26. For example, the metal silicide layer 24 is made of HfₓSiO_{y}, TaₓSiO_{y}, ZrₓSiO_{y}, LaₓSiO_{y}, AlₓSiO_{y}, and TiₓSiO_{y}. In an embodiment, exemplary high-k dielectric materials of the metal silicide layer 24 include at least two high-k metals compounding with silicon oxide; for example, HfTaSiO, HfTiO, HfZrSiO, and hafnium dioxide-alumina silicon (HfO2-Al2O3) alloy. The metal silicide layer 24 includes a high-k metal with a concentration from about 10% to 40% of a total dopant concentration of the metal silicide layer 24. In addition, the metal silicide layer 24 includes a thickness from about 10 angstroms to 50 angstroms. By having a low standard electrode potential, the metal silicide layer 24 is not subject to oxidation or reduction. During a subsequent thermal process, the metal silicide layer 24 is capable of staying stable and unreacted. In addition, the metal silicide layer 24 also includes high-k metals. Oxygen atoms in the metal silicide layer 24 are already bonded by the high-k metal atoms. Thus, the high-k metal atoms of the first and second high-k dielectric layers (22, 26) have difficulty grabbing oxygen atoms from the metal silicide layer 24. In addition, due to its condensed property, the metal silicide layer 24 serves as a diffusion barrier between the first and second high-k dielectric layers (22, 26). The metal silicide layer 24 prevents the high-k atoms from penetrating into an adjacent high-k dielectric layer during a subsequent thermal process. By using the metal silicide layer 24, the first high-k dielectric layer 22 prevents the negative charge property from being neutralized or oxidized. Since negative charges are included in the first high-k dielectric layer 22, positive charges or holes are accumulated near an interface of the substrate 10 and the first high-k dielectric layer 22. The accumulated holes near the first high-k dielectric layer 22 block electrons. The electrons cannot form a leakage current or a dark current. The accumulated holes can be regarded as a barrier that prevents the formation of leakage current. The positive charges or holes provide isolation and reduce electrical crosstalk.

In an embodiment, the metal silicide layer 24 includes nitrogen with a concentration from about 5% to 10% of a total dopant concentration of the metal silicide layer 24. For example, the metal silicide layer 24 is made of HfSiOxN or TaSiOyN. The nitrogen atoms compounding with the metal silicide layer 24 provide a condensed and stable layer. In an embodiment, the metal silicide layer 24 includes carbon with a concentration from about 5% to 20% of a total dopant concentration of the metal silicide layer 24. For example, the metal silicide layer 24 is made of HfSiOxC or TaSiOyC. The nitrogen or carbon compounds have a low standard electrode potential so that they are not subject to oxidation or reduction. As such, the metal silicide layer 24 serves as a diffusion barrier between the first and second high-k dielectric layers (22, 26).

In some embodiments, a buffer layer (not shown) is disposed between the substrate 10 and the metal grid 42. The buffer layer serves as a planarization for the BSI image sensor device 100. Material of the buffer layer includes dielectric materials, such as silicon oxide. For example, an oxide layer is disposed between the substrate 10 and the first high-k dielectric layer 22. The oxide layer is able to repair defects and vacancies of the back side 10B after a thinning process. The oxide layer also provides a planarization for the metal grid 42. In some embodiments, the buffer layer includes bottom anti-reflective coating (BARC). It is appreciated that buffer layers may have different structures, be formed of different materials, and/or have a different number of layers other than illustrated. In some embodiments, a thin p+ layer is formed between the substrate 10 and the first high-k dielectric layer 22 so as to increase the number of photons converted into electrons. The thin p+ layer helps to reduce the leakage of the radiation-sensing region 31.

The metal grid 42 is located over the back side 10B. The metal grid 42 is configured to guide radiation waves into the radiation-sensing regions 31. The metal grid 42 reflects the radiation wave 80 when photons of the radiation wave 80 hit the metal grid 42. In some embodiments, the metal grid 42 is made of reflective materials, for example, AlCu, W, SiN or metal. The dielectric layer 45 is filled in the metal grid 42 and aligns to the radiation-sensing regions 31. The metal grid 42 separates the dielectric layer 45 from adjacent sensor pixels. The dielectric layer 45 allows the radiation waves to penetrate through the dielectric layer 45. The dielectric layer 45 is made of dielectric materials, such as silicon oxide.

The color filters 51 are disposed on the dielectric layer 45 and substantially over the radiation-sensing regions 31. Each of the color filters 51 aligns with the radiation-sensing regions 31 respectively. The color filters 51 are configured to filter visible light, such as that of a red, green, or blue wavelength. The color filters 51 include suitable material for optical structures. For example, the color filters 51 include a dye-based (or pigment-based) polymer for filtering out a specific frequency band. Alternatively, the color filters 51 include a resin or other organic-based material having color pigments. The micro lenses 63 are disposed over the color filters 51. The micro lenses 63 focus the radiation wave 80 on the respective radiation-sensing regions 31. The micro lenses 63 include a suitable material with a variety of shapes and sizes depending on an index of refraction of the material.

FIG. 1B is a zoom-in diagram illustrating the BSI image sensor device 100. The substrate 10 includes an array of the radiation-sensing regions 31. The radiation-sensing regions 31 are located near the back side 10B. The radiation-sensing regions 31 are configured to detect a radiation wave entering from the back side 10B of the substrate 10. The first high-k dielectric layer 22 is disposed over the back side 10B of the substrate 10. The metal silicide layer 24 is disposed on the first high-k dielectric layer 22. The second high-k dielectric layer 26 is disposed on the metal silicide layer 24. The metal silicide layer 24 is made from a compound of silicon oxide and at least one high-k metal. Oxygen atoms in the metal silicide layer 24 have been bonded by the high-k metal so that they cannot serve as acceptors for adjacent high-k dielectric layers. In addition, the metal silicide layer 24 has a lower standard electrode potential than adjacent high-k dielectric layers. The metal silicide layer 24 has a better chemical stability and is hard to decompose. As such, the metal silicide layer 24 serves as a diffusion barrier between the first high-k dielectric layer 22 and the second high-k dielectric layer 26. Further, since the metal silicide layer 24 also includes an oxide and high-k metals, the metal silicide layer 24 provides a better adhesion for adjacent high-k dielectric layers.

The metal silicide layer 24 prevents the high-k atoms of the second high-k dielectric layer 26 from penetrating into the first high-k dielectric layer 22. Therefore, the negative charge property in the first high-k dielectric layer 22 remains as shown in FIG. 1C. Since negative charges are included in the first high-k dielectric layer 22, positive charges or holes are accumulated near the back side 10B and block electrons. Because the electrons are blocked, they cannot form a leakage current or a dark current. Similarly, the first high-k dielectric layer 22 is able to neutralize the influence of defects near the back side 10B. The first high-k dielectric layer 22 reduces electrical crosstalk.

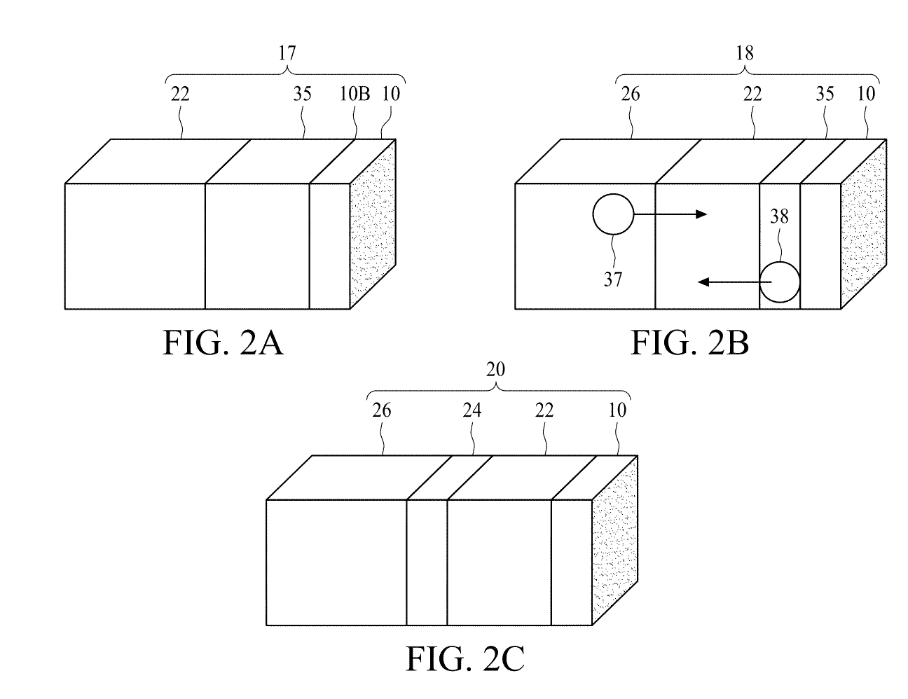

FIGS. 2A-2C are three-dimensional views illustrating multilayer structures in accordance with some embodiments of the present disclosure. These figures explain how the metal silicide layer 24 works. Referring to FIG. 2A, a multilayer structure 17 is disposed adjacent to the substrate 10. An oxide layer 35 is sandwiched by the substrate 10 and the first high-k dielectric layer 22. The oxide layer 35 is configured to repair the back side 10B of the substrate 10. The first high-k dielectric layer 22 provides a negative charge layer so as to reduce electrical crosstalk in the substrate 10. However, since the single high-k dielectric layer is unstable and vulnerable to oxidation, the negative charge property disappears. As such, a second high-k dielectric layer 26 connects with the first high-k dielectric layer 22 as shown in FIG. 2B. The second high-k dielectric layer 26 is made of a high-k dielectric material with a lower standard electrode potential. Accordingly, the second high-k dielectric layer 26 provides chemical stability and oxidation endurance for the first high-k dielectric layer 22. However, in subsequent thermal processes, high-k atoms 37 in the second high-k dielectric layer 26 are driven by thermal energy so as to penetrate into the first high-k dielectric layer 22. Meanwhile, the oxide layer 35 provides oxygen atoms 38 as acceptors that diffuse into the first high-k dielectric layer 22. The high-k atoms 37 are regarded as donors. The oxygen atoms 38 and the high-k atoms 37 combine and react in the first high-k dielectric layer 22. That is, the high-k atoms 37 are oxidized due to their high standard electrode potential. The composition of the first high-k dielectric layer 22 is changed so that the negative charge property disappears. In order to block the diffusion of the high-k atoms 37, a metal silicide layer 24 is disposed between the first high-k dielectric layer 22 and the second high-k dielectric layer 26 as shown in FIG. 2C. The metal silicide layer 24 is made from a compound of silicon oxide and at least one high-k metal. The metal silicide layer 24 thus has a lower standard electrode potential and a higher oxidation endurance. The metal silicide layer 24 serves as a diffusion barrier to block the high-k atoms 37. Therefore, the high-k atoms 37 cannot penetrate into the first high-k dielectric layer 22. The negative charge property in the first high-k dielectric layer 22 remains. The multilayer structure 20 formed on the back side 10B can reduce influence of the dark current and electrical crosstalk.

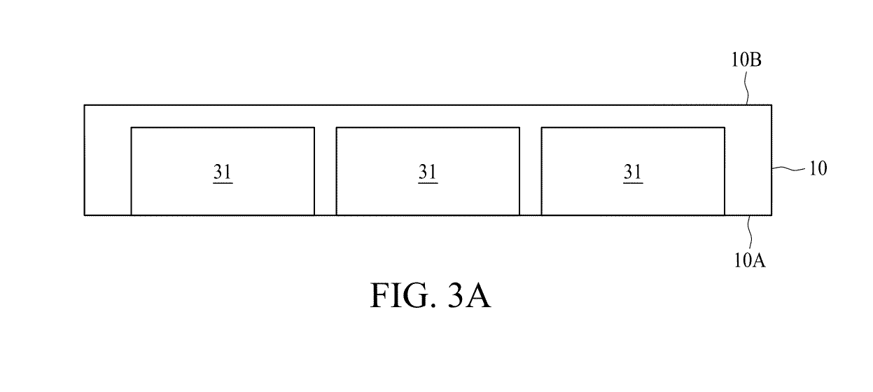

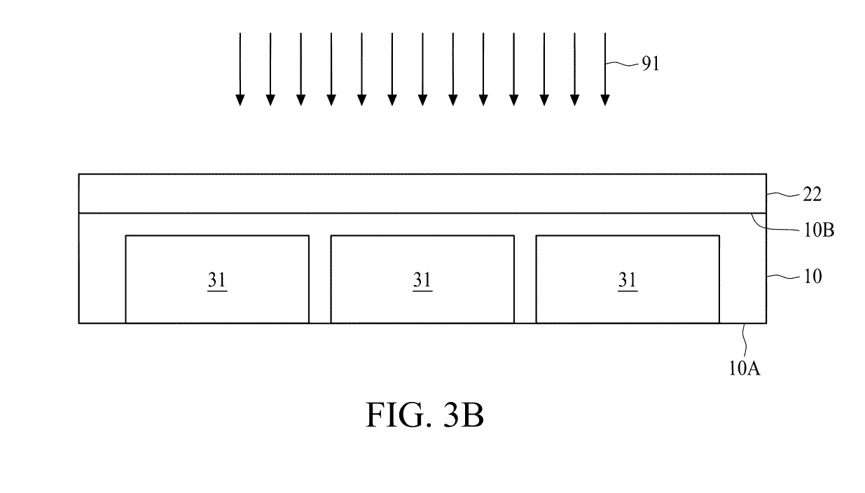

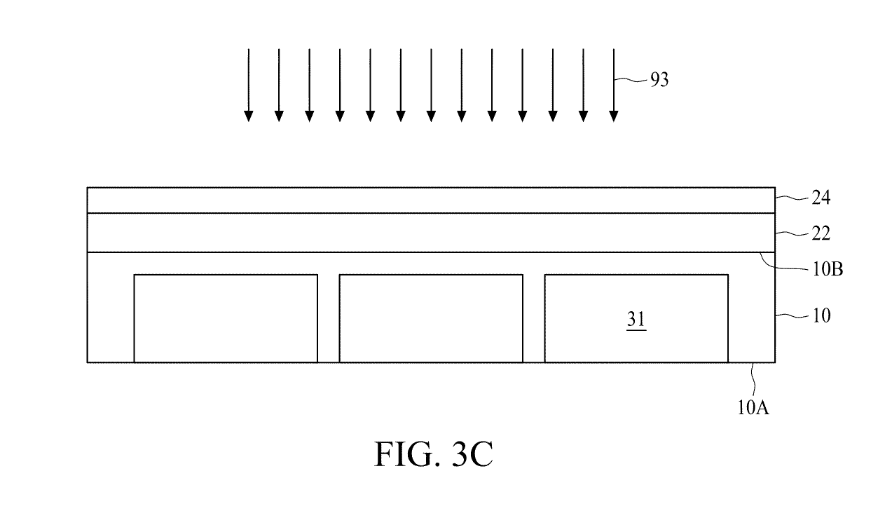

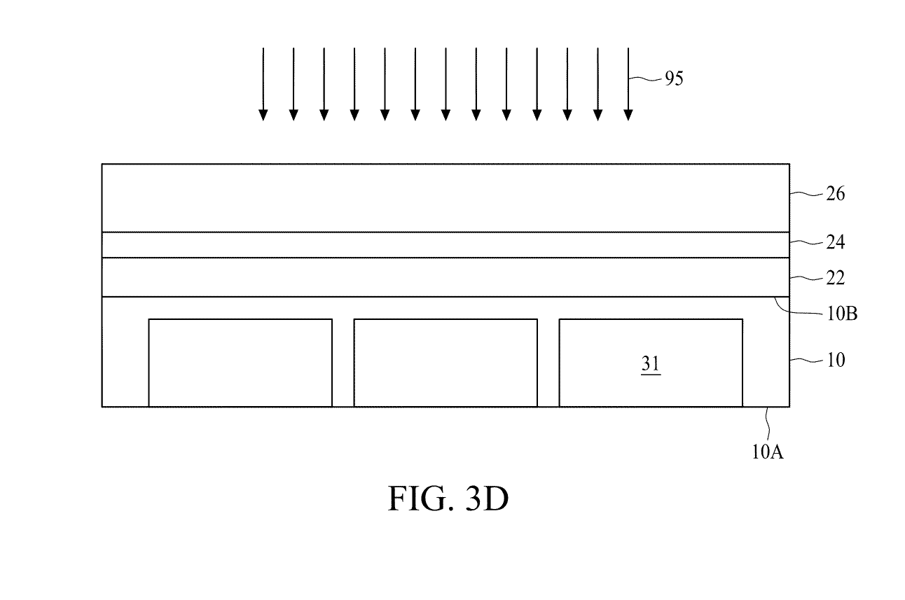

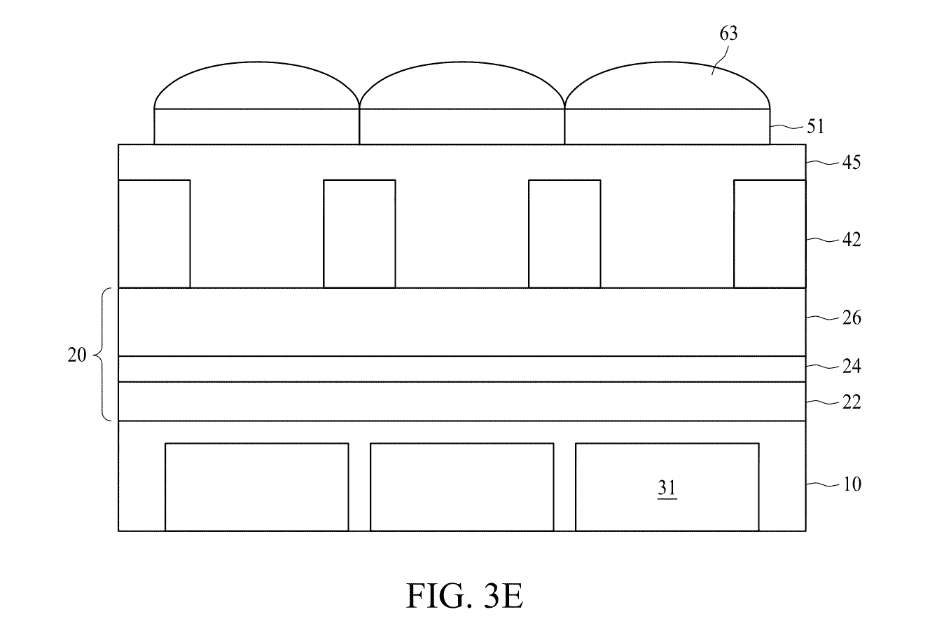

FIGS. 3A-3E represent a method of manufacturing a backside illuminated (BSI) image sensor device 100 as in FIG. 1 in accordance with some embodiments of the present disclosure. Each figure represents a stage of the method in a cross-sectional perspective view.

Referring to FIG. 3A, a substrate 10 having a front side 10A and a back side 10B is provided. A local oxidation of silicon (LOCOS) or a Shallow Trench Isolation (STI) process is performed to define active regions of image pixels on the front side 10A. Thus, the substrate 10 includes shallow trench isolations (not shown) on the front side 10A configured to isolate image pixels. Later, at least one image pixel is formed on the front side 10A. The image pixels are formed adjacent to the shallow trench isolations. During formation of the image pixels, at least one ion implantation is employed to form radiation-sensing regions and floating diffusion regions with different levels of depth and energy. For example, an ion implantation is used to form radiation-sensing regions 31. The radiation-sensing regions 31 are formed by performing an ion implantation process on the front side 10A. The ion implantation process implants the substrate 10 separately with n-type and p-type dopants so as to form a photodiode or a pinned diode. The position or configuration of the radiation-sensing regions 31 is adjusted by tuning an implantation energy level of the implantation process.

After the image pixels and the radiation-sensing regions 31 are formed, the substrate 10 is held by a carrier (not shown) and the back side 10B is in an upward position. A thinning process (not shown) is performed in order to thin the substrate 10 from the back side 10B. For example, the thinning process includes a Chemical Mechanical Polishing (CMP)/Planarization process. Alternatively, the thinning process includes a diamond scrubbing process, a grinding process, or other suitable techniques. A substantial amount of material may be removed from the back side 10B by using the thinning process. In an embodiment, the thinning process is performed until portions of the radiation-sensing regions 31 are exposed. After the thinning process, the substrate 10 is thin enough so that the radiation-sensing regions 31 can efficiently receive radiation waves that enter from the back side 10B.

Referring to FIG. 3B, after the step of thinning, a first high-k dielectric layer 22 is formed on the back side 10B by a deposition 91 illustrated as arrows. The first high-k dielectric layer 22 is formed by using a deposition technique that can form conformal dielectric layers, such as atomic layer deposition (ALD) and chemical vapor deposition (CVD). The deposition 91 includes a precursor selected from a group consisting of HfO₂ and La₂O₃. The first high-k dielectric layer 22 is able to repair damages and defects that are induced by a thinning process. The defects on the back side 10B are repaired and depleted so that the dark current can be reduced. In addition, the first high-k dielectric layer 22 includes negative charges so that positive charges or holes are accumulated near the back side 10B and block electrons. The first high-k dielectric layer 22 also reduces electrical crosstalk.

Referring to FIG. 3C, a deposition 93 illustrated as arrows is performed to form a metal silicide layer 24. The deposition 93 includes a precursor having silicon oxide and at least one high-k metal. In an embodiment, the deposition 93 further includes an oxidation process, such as wet or dry thermal oxidation in an ambient with an oxide, H₂O, NO, or a combination thereof, or by chemical vapor deposition (CVD) techniques using tetra-ethyl-ortho-silicate (TEOS) and oxygen as a precursor. The high-k metal includes, for example, hafnium, tantalum, zirconium, lanthanum and titanium. In an embodiment, the deposition 93 includes a precursor having silicon oxide, at least one high-k metal and carbon. In an embodiment, the deposition 93 includes a precursor having silicon oxide, at least one high-k metal and nitrogen. After the deposition 93, an annealing process is performed to repair the defects formed in the metal silicide layer 24. The metal silicide layer 24 serves as a diffusion barrier in order to block diffused high-k atoms. Due to the metal silicide layer 24, high-k atoms of an adjacent high-k dielectric layer are blocked in a sequential thermal process. In addition, the metal silicide layer 24 provides a better adhesion for a next high-k dielectric layer.

Referring to FIG. 3D, a second high-k dielectric layer 26 is formed on the metal silicide layer 24 by a deposition 95 illustrated as arrows. The deposition 95 includes a precursor selected from a group consisting of ZrO₂, Ta₂O₅, Al₂O₃, and TiO₂. The second high-k dielectric layer 26 includes a lower standard electrode potential than the first high-k dielectric layer 22. As such, the second high-k dielectric layer 26 is able to stabilize the first high-k dielectric layer 22.

Referring to FIG. 3E, a metal grid 42 is formed on the second high-k dielectric layer 26. The metal grid 42 is formed by depositing a metal(s) or a metal alloy layer, for example, tungsten, aluminum, copper, and/or the like. The metal layer may have a single-layer structure with a single layer therein, or a composite structure including a plurality of stacked layers. Later, a photoresist layer (not shown) is formed over the metal layer. An etching process is performed on the metal grid 42. The etching process is an anisotropic or isotropic etch that includes a reactive ion etch (RIE) process. The metal layer 31 is etched to match the pattern of the photoresist layer. A remaining portion of the metal layer forms the metal grid 42.

A deposition is performed to form a dielectric layer 45. The deposition includes dielectric materials, such silicon oxide, silicon nitride, silicon carbon, or SiON. The dielectric layer 45 is formed over the back side 10B and fills up the metal grid 42. Later, color filters 51 are deposited on the dielectric layer 45. Each of the color filters 51 includes one of a variety of different colors; for example, red, green, blue, and white. Each color filter 51 aligns with a corresponding one of the radiation-sensing regions 31. Next, micro lenses 63 are formed over the color filters 51 and the metal grid 42. The micro lenses 63 are formed by, for example, applying and patterning a positive-type photoresist (not shown) over the color filters 51. Once formed, the patterned photoresist may then be baked to round the photoresist into a curved micro lens.

The metal silicide layer 24 provides a diffusion block layer and a better adhesion between the first and second high-k dielectric layers (22, 26). Due to the metal silicide layer 24, high-k atoms of the second high-k dielectric layer 26 are blocked in a sequential thermal process. The negative charge property of the first high-k dielectric layer 22 remains on the back side 10B of the substrate 10. Thus, the dark current and white pixel degradation are reduced. In addition, the first high-k dielectric layer 22 is able to neutralize the influence of defects near the back side 10B. The first high-k dielectric layer 22 reduces electrical crosstalk.

A backside illuminated (BSI) image sensor device includes: a substrate including a front side and a back side; a multilayer structure over the back side; and a radiation-sensing region in the substrate. The radiation-sensing region is configured to receive a radiation wave entering from the back side and transmitting through the multilayer structure. The multilayer structure includes a first high-k dielectric layer, a metal silicide layer and a second high-k dielectric layer. The first high-k dielectric layer is located over the back side. The metal silicide layer is sandwiched between the first high-k dielectric layer and the second high-k dielectric layer.

In some embodiments, the metal silicide layer includes a high-k metal that is the same as that of the first high-k dielectric layer or the second high-k dielectric layer.

In some embodiments, the metal silicide layer includes nitrogen with a concentration from about 5% to 15% of a total dopant concentration of the metal silicide layer.

In some embodiments, the metal silicide layer includes carbon with a concentration from about 5% to 20% of a total dopant concentration of the metal silicide layer.

In some embodiments, the first high-k dielectric layer includes negative charges.

In some embodiments, the second high-k dielectric layer has a lower standard electrode potential than the first high-k dielectric layer.

In some embodiments, the multilayer structure includes a thickness from about 100 angstroms to 1000 angstroms.

In some embodiments, the BSI image sensor device further includes a thickness ratio between the first high-k dielectric layer, the metal silicide layer and the second high-k dielectric layer, which is about 5:1:50.

A backside illuminated (BSI) image sensor device includes: a substrate including an array of radiation-sensing regions; a first high-k dielectric layer over the back side of the substrate; a metal silicide layer on the first high-k dielectric layer; and a second high-k dielectric layer on the metal silicide layer. The array of radiation-sensing regions is configured to detect a radiation wave entering from a back side of the substrate.

In some embodiments, the metal silicide layer includes a high-k metal different from that of the first high-k dielectric layer or the second high-k dielectric layer.

In some embodiments, the first high-k dielectric layer includes a high-k metal different from that of the second high-k dielectric layer.

In some embodiments, the metal silicide layer includes a high-k metal with a concentration from about 20% to 50% of a total dopant concentration of the metal silicide layer.

In some embodiments, the first high-k dielectric layer is selected from a group consisting of HfO₂ and La₂O₃.

In some embodiments, the second high-k dielectric layer is selected from a group consisting of ZrO₂, Ta₂O₅, Al₂O₃, and TiO₂.

In some embodiments, the first high-k dielectric layer includes a thickness from about 10 angstroms to 100 angstroms, and the second high-k dielectric layer includes a thickness from about 80 angstroms to 900 angstroms.

In some embodiments, the metal silicide layer includes a thickness from about 10 angstroms to 50 angstroms.

In some embodiments, the BSI image sensor device further includes an oxide layer between the substrate and the first high-k dielectric layer.

A method for forming a backside illuminated (BSI) image sensor device includes: providing a substrate including a radiation-sensing region formed in the substrate; forming a first high-k dielectric layer over the back side; forming a metal silicide layer on the first high-k dielectric layer; and forming a second high-k dielectric layer on the metal silicide layer. The radiation-sensing region is configured to detect a radiation wave entering from a back side of the substrate.

In some embodiments, the first high-k dielectric layer is deposited by a precursor selected from a group consisting of HfO₂ and La₂O₃. The second high-k dielectric layer is deposited by a precursor selected from a group consisting of ZrO₂, Ta₂O₅, Al₂O₃, and TiO₂.

In some embodiments, the metal silicide layer is deposited by a precursor including silicon oxide and a high-k metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A backside illuminated (BSI) image sensor device, comprising:
a substrate including a front side and a back side;
a multilayer structure over the back side,
wherein the multilayer structure comprises a first high-k dielectric layer, a metal silicide layer and a second high-k dielectric layer, the first high-k dielectric layer is located over the back side, the metal silicide layer is sandwiched between the first high-k dielectric layer and the second high-k dielectric layer; and
a radiation-sensing region in the substrate, wherein the radiation-sensing region is configured to receive a radiation wave entering from the back side and transmitting through the multilayer structure.

2. The BSI image sensor device of claim 1, wherein the metal silicide layer comprises a high-k metal that is the same as that of the first high-k dielectric layer or the second high-k dielectric layer.

3. The BSI image sensor device of claim 1, wherein the metal silicide layer comprises nitrogen with a concentration from about 5% to 15% of a total dopant concentration of the metal silicide layer.

4. The BSI image sensor device of claim 1, wherein the metal silicide layer comprises carbon with a concentration from about 5% to 20% of a total dopant concentration of the metal silicide layer.

5. The BSI image sensor device of claim 1, wherein the first high-k dielectric layer comprises negative charges.

6. The BSI image sensor device of claim 1, wherein the second high-k dielectric layer has a lower standard electrode potential than the first high-k dielectric layer.

7. The BSI image sensor device of claim 1, wherein the multilayer structure comprises a thickness from about 100 angstroms to 1000 angstroms.

8. The BSI image sensor device of claim 1, further comprising a thickness ratio between the first high-k dielectric layer, the metal silicide layer and the second high-k dielectric layer, which is about 5:1:50.

9. A backside illuminated (BSI) image sensor device, comprising:
a substrate including an array of radiation-sensing regions, and the array of radiation-sensing regions is configured to detect a radiation wave entering from a back side of the substrate;
a first high-k dielectric layer over the back side of the substrate;
a metal silicide layer on the first high-k dielectric layer; and
a second high-k dielectric layer on the metal silicide layer.

10. The BSI image sensor device of claim 9, wherein the metal silicide layer comprises a high-k metal different from that of the first high-k dielectric layer or the second high-k dielectric layer.

11. The BSI image sensor device of claim 9, wherein the first high-k dielectric layer comprises a high-k metal different from that of the second high-k dielectric layer.

12. The BSI image sensor device of claim 9, wherein the metal silicide layer comprises a high-k metal with a concentration from about 20% to 50% of a total dopant concentration of the metal silicide layer.

13. The BSI image sensor device of claim 9, wherein the first high-k dielectric layer is selected from a group consisting of HfO₂ and La₂O₃.

14. The BSI image sensor device of claim 9, wherein the second high-k dielectric layer is selected from a group consisting of ZrO₂, Ta₂O₅, Al₂O₃, and TiO₂.

15. The BSI image sensor device of claim 9, wherein the first high-k dielectric layer comprises a thickness from about 10 angstroms to 100 angstroms, and the second high-k dielectric layer comprises a thickness from about 80 angstroms to 900 angstroms.

16. The BSI image sensor device of claim 9, wherein the metal silicide layer comprises a thickness from about 10 angstroms to 50 angstroms.

17. The BSI image sensor device of claim 9, further comprising an oxide layer between the substrate and the first high-k dielectric layer.

18. A method for forming a backside illuminated (BSI) image sensor device, comprising:
providing a substrate including a radiation-sensing region formed in the substrate, and the radiation-sensing region is configured to detect a radiation wave entering from a back side of the substrate;
forming a first high-k dielectric layer over the back side;
forming a metal silicide layer on the first high-k dielectric layer; and
forming a second high-k dielectric layer on the metal silicide layer.

19. The method of claim 18, wherein the first high-k dielectric layer is deposited by a precursor selected from a group consisting of HfO₂ and La₂O₃, and the second high-k dielectric layer is deposited by a precursor selected from a group consisting of ZrO₂, Ta₂O₅, Al₂O₃, and TiO₂.

20. The method of claim 18, wherein the metal silicide layer is deposited by a precursor comprising silicon oxide and a high-k metal.
